(19) United States
(12) Patent Application Publication
(10) Pub. No.: US 2023/0307500 A1
(43) Pub. Date: Sep. 28, 2023

(54) METHOD FOR MANUFACTURING SILICON CARBIDE SEMICONDUCTOR DEVICE AND SILICON CARBIDE SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Takuma SUZUKI, Himeji Hyogo (JP)

(21) Appl. No.: 17/892,809

(22) Filed: Aug. 22, 2022

(30) Foreign Application Priority Data
Mar. 24, 2022 (JP) 2022-047832

(51) Int. Cl. H01L 29/16; H01L 29/66; H01L 21/04; H01L 29/06

(52) U.S. Cl. CPC H01L 29/1608; H01L 29/66068; H01L 21/0465; H01L 29/0607

(57) ABSTRACT

According to one embodiment, a method for manufacturing a silicon carbide semiconductor device. The method includes forming a semiconductor layer on a substrate. The method includes forming a first semiconductor region by implanting an impurity of a first conductivity type into the semiconductor layer. The first semiconductor region has a first concentration of the first conductivity type. The method includes forming a first semiconductor pillar portion and a second semiconductor pillar portion by implanting an impurity of a second conductivity type into a plurality of locations of the first semiconductor region. The first semiconductor pillar portion is of the first conductivity type. The second semiconductor pillar portion has a second concentration of the second conductivity type and is adjacent to the first semiconductor pillar portion. The method includes repeating the forming of the semiconductor layer, forming of the first semiconductor region, and the first and second semiconductor pillar portions.

### CROSS-REFERENCE TO RELATED APPLICATIONS

This application is based upon and claims the benefit of priority from Japanese Patent Application No.2022-047832, filed on Mar. 24, 2022; the entire contents of which are incorporated herein by reference.

### FIELD

Embodiments described herein relate generally to a method for manufacturing a silicon carbide semiconductor device and a silicon carbide semiconductor device.

### BACKGROUND

A semiconductor device that uses silicon carbide is known.

### BRIEF DESCRIPTION OF THE DRAWINGS

FIG. 1 is a schematic cross-sectional view showing an example of a cross section of a silicon carbide semiconductor device in the first embodiments.

FIG. 2 is a flowchart showing an example of a method for manufacturing the silicon carbide semiconductor device in the first embodiment.

FIG. 3 is a schematic views of semiconductor layers in process when manufacturing the silicon carbide semiconductor device in the first embodiments.

FIG. 4 is a schematic views of semiconductor layers in process when manufacturing the silicon carbide semiconductor device in the first embodiments.

FIG. 5 is a schematic views of semiconductor layers in process when manufacturing the silicon carbide semiconductor device in the first embodiments.

FIG. 6 is a schematic views of semiconductor layers in process when manufacturing the silicon carbide semiconductor device in the first embodiments.

FIG. 7 is a schematic views of semiconductor layers in process when manufacturing the silicon carbide semiconductor device in the first embodiments.

FIG. 8 is a schematic views of semiconductor layers in process when manufacturing the silicon carbide semiconductor device in the first embodiments.

FIG. 9 is a schematic views of semiconductor layers in process when manufacturing the silicon carbide semiconductor device in the first embodiments.

FIG. 10 is a schematic views of semiconductor elements of silicon carbide semiconductor device in the first embodiments.

FIG. 11 shows an example of the measurement result of the n-type impurity of silicon carbide semiconductor device in the first embodiments.

FIG. 12 shows an example of a measurement result of the p-type impurity of FIG. 12 shows an example of a measurement result of the p-type impurity.

FIG. 13 is a schematic cross-sectional view showing an example of the structure of the end portion of a silicon carbide semiconductor device of the second embodiment.

FIG. 14 is a schematic cross-sectional view showing another example of the structure of the end portion of a silicon carbide semiconductor device of the second embodiment.

### DETAILED DESCRIPTION

In general, according to one embodiment, a method for manufacturing a silicon carbide semiconductor device, the method comprising: forming a semiconductor layer on a substrate, the substrate including silicon carbide; forming a first semiconductor region by implanting an impurity of a first conductivity type into the semiconductor layer, the first semiconductor region having a first concentration of the first conductivity type; forming a first semiconductor pillar portion and a second semiconductor pillar portion by implanting an impurity of a second conductivity type into a plurality of locations of the first semiconductor region, the first semiconductor pillar portion being of the first conductivity type, the second semiconductor pillar portion having a second concentration of the second conductivity type and being adjacent to the first semiconductor pillar portion; and repeating the forming of the semiconductor layer, the forming of the first semiconductor region, and the forming of the first and second semiconductor pillar portions.

Embodiments of the invention will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

In the specification and drawings, components similar to those described previously or illustrated in an antecedent drawing are marked with the same reference numerals; and a detailed description is omitted as appropriate.

### First Embodiment

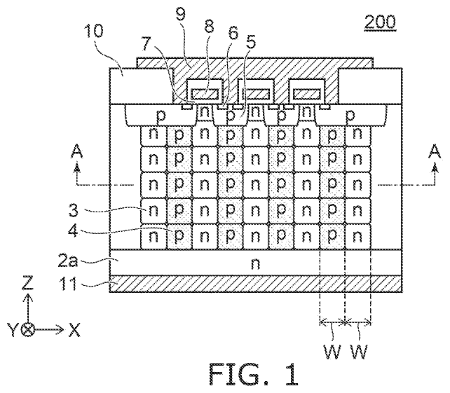

FIG. 1 is a schematic cross-sectional view showing an example of a cross section of a silicon carbide semiconductor device 200 that is manufactured by a manufacturing method of the embodiment and includes silicon carbide (SiC) as a material. According to the embodiment, a first conductivity type is described as an n-type; and a second conductivity type is described as a p-type. The arrangements and configurations of the portions are described using an X-axis, a Y-axis, and a Z-axis shown in the drawings. The X-axis, the Y-axis, and the Z-axis are orthogonal to each other and respectively represent an X-direction, a Y-direction, and a Z-direction. The Z-direction may be described as up, and the opposite direction may be described as down.

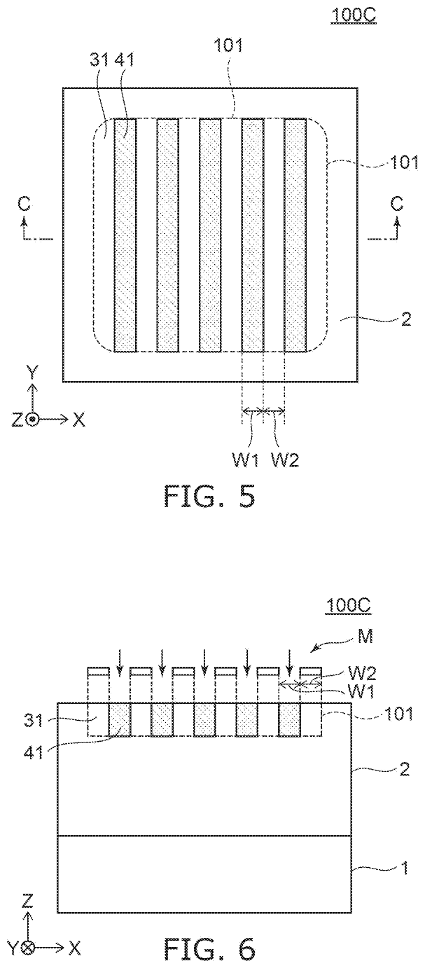

As shown in FIG. 1, the silicon carbide semiconductor device 200 includes a first semiconductor pillar region 3 made of an n-type silicon carbide and a second semiconductor pillar region 4 made of a p-type silicon carbide that are periodically arranged on a main surface of a semiconductor layer (a first semiconductor region) 2a made of n-type silicon carbide in a direction (the X-direction) substantially parallel to the main surface of the semiconductor layer 2a. According to the embodiment as shown in FIG. 5 below, the planar patterns of the first and second semiconductor pillar regions 3 and 4 are stripe shapes of a width W. “Width” refers to the length in the direction in which the first semiconductor pillar region 3 and the second semiconductor pillar region 4 are periodically arranged. “Stripe shape” refers to a structure in which the first semiconductor pillar region 3 and the second semiconductor pillar region 4 each extend in a direction (the Z-direction of FIG. 1) orthogonal to the direction in which the first semiconductor pillar region 3 and the second semiconductor pillar region 4 are periodically arranged (the X-direction in the drawing). Thus, the silicon carbide semiconductor device 200 of the embodiment has a so-called super junction structure. The widths of the first and second semiconductor pillar regions 3 and 4 each are the width W. The width W is, for example, 2 μm.

For example, a base region 5 that is made of p-type silicon carbide is formed on the second semiconductor pillar region 4 in contact with the second semiconductor pillar region 4. For example, a source region (a second semiconductor region) 6 made of n-type silicon carbide is formed at the surface of the base region 5. The planar patterns of the base region 5 and the source region 6 each are, for example, stripe shapes.

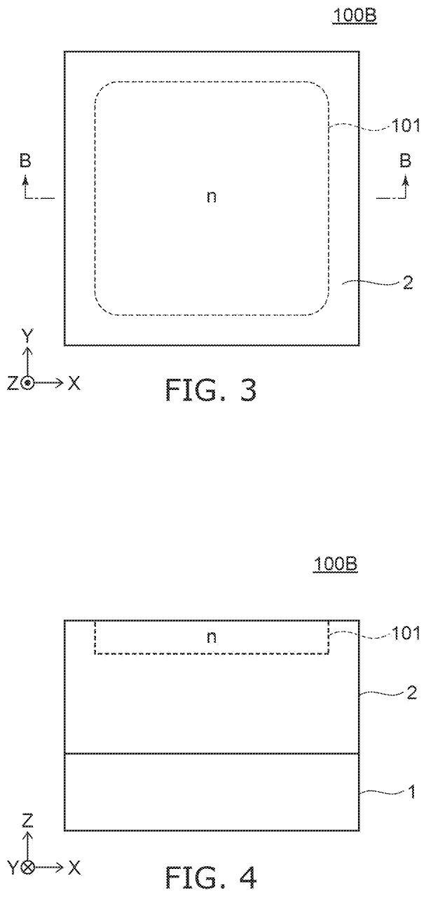

An insulating film 7 is located on a portion from the first semiconductor pillar region 3 over the base region 5 to the source region 6. The insulating film 7 is, for example, an oxide film. A control electrode 8 is located on the insulating film 7. An insulating film 10 is formed at the top of the base region 5 at the end portion. Here, the base region 5 at the end portion is the base region at the outermost edge of the active region. The active region is located at the main surface of the semiconductor layer 2a and is the region for performing major operations of the silicon carbide semiconductor device 200. In other words, the active region is the region through which a current flows in the on-operation of the silicon carbide semiconductor device 200. For example, in FIG. 3 below, the active region is shown as an active region 101. The base regions 5 that are positioned at the most terminal ends in the X-direction of the active region 101 are the base regions at the end portions.

A source electrode (a second major electrode) 9 is formed on a portion of the source region 6, on a portion of the base region 5 between the source regions 6, and from the side surface to a portion of the top of the insulating film 10. The source electrode 9 is electrically connected with the base region 5 and the source region 6. A drain electrode (a first major electrode) 11 is formed at the surface of the semiconductor layer 2a at the side opposite to the main surface. The drain electrode 11 is electrically connected with the semiconductor layer 2a.

When a prescribed voltage is applied to the control electrode 8, a channel is formed at the surface vicinity of the base region 5 directly under the control electrode 8; and the source region 6 and the first semiconductor pillar region 3 conduct. As a result, a major current path is formed between the source electrode 9 and the drain electrode 11 via the source region 6, the first semiconductor pillar region 3, and the semiconductor layer 2a; and the on-state is set between the major electrodes. Thus, the silicon carbide semiconductor device 200 is configured to be capable of conducting. When the voltage that is applied to the control electrode 8 is stopped, the channel that was formed at the surface vicinity of the base region 5 directly under the control electrode 8 disappears, and the source region 6 and the first semiconductor pillar region 3 no longer conduct. As a result, the major current path is not formed between the source electrode 9 and the drain electrode 11; and the off-state is set between the major electrodes. Thus, the on-state and the off-state are switched in the silicon carbide semiconductor device 200.

In the silicon carbide semiconductor device 200 that has the super junction structure, a depletion layer spreads between the adjacent first semiconductor pillar region 3 and second semiconductor pillar region 4 as the drain-source voltage (Vds) rises at turn-off. The depletion layer continues to spread as Vds rises; and the first semiconductor pillar region 3 and the second semiconductor pillar region 4 are fully depleted. A depletion layer that has the pillar depth of the first and second semiconductor pillar regions 3 and 4 is generated thereby. The breakdown voltage of the silicon carbide semiconductor device 200 can be maintained by the depletion layer.

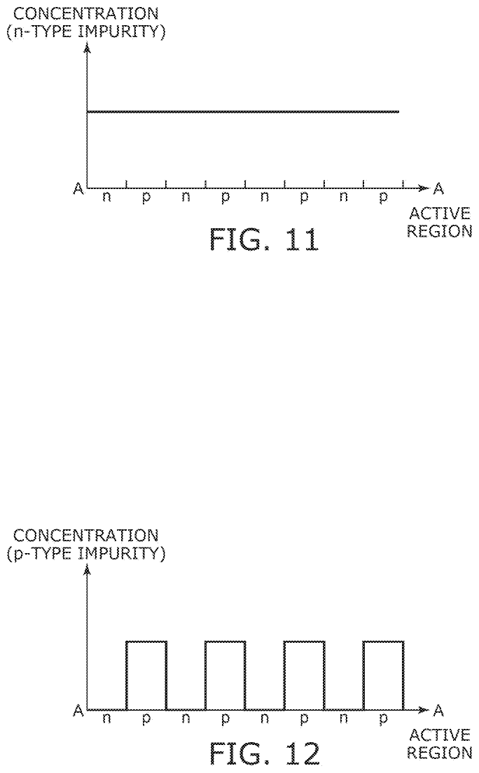

As will be described below using FIGS. 11 and 12, A-A shown in FIG. 1 shows an example of the pillar depths of the first and second semiconductor pillar regions 3 and 4.

Although FIG. 1 as well as FIGS. 3 to 10, FIG. 13, and FIG. 14 below in the embodiments show an example of the number of components included in the silicon carbide semiconductor device 200 such as the first semiconductor pillar region 3, the second semiconductor pillar region 4, etc., the number of components included in the silicon carbide semiconductor device 200 is modifiable as appropriate.

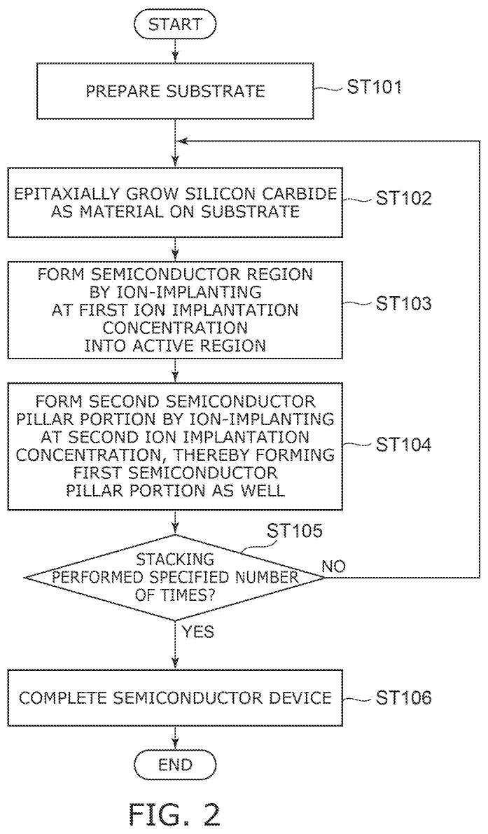

FIG. 2 is a flowchart showing an example of a method for manufacturing the silicon carbide semiconductor device 200 of the embodiment.

FIGS. 3 to 10 are schematic views of semiconductor layers in each process when manufacturing the silicon carbide semiconductor device 200.

FIGS. 3 and 5 are schematic top views showing examples of semiconductor layers; and FIG. 4 and FIGS. 6 to 10 are schematic cross-sectional views showing the examples of the semiconductor layers.

FIGS. 4 and 6 are respectively a B-B cross section of FIG. 3 and a C-C cross section of FIG. 5.

The method for manufacturing the silicon carbide semiconductor device 200 will now be described.

First, a substrate 1 that includes silicon carbide is prepared (ST101); and the substrate 1 is epitaxially grown under prescribed conditions (ST102). According to the embodiment, the conductivity type of the epitaxial layer is, for example, the n-type. According to the embodiment, the impurity that is included in the epitaxial layer is of the n-type and is, for example, nitrogen (N). The n-type impurity concentration is 1×10¹⁶/cm³.

Then, an n-type semiconductor region that has a first concentration is formed as shown in FIGS. 3 and 4 by ion-implanting an n-type impurity at a first ion implantation concentration into the entire region of the active region 101 (ST103). The n-type impurity is, for example, nitrogen (N) or phosphorus (P). According to the embodiment, the first concentration is, for example, 1×10¹⁷/cm³. For example, when the n-type impurity concentration of the epitaxial layer is 1×10¹⁶/cm³ (0.1×10¹⁷/cm³) as described above, the first ion implantation concentration is set to 0.9×10¹⁷×cm³, and when summed, the first concentration (the n-type) becomes 1.0×10¹⁷/cm³. A first carrier concentration (the electrons) of the active region 101 becomes 1.0×10¹⁷/cm³. A description of the carrier concentration is described below.

Continuing, a p-type second semiconductor pillar portion 41 that has a second concentration is formed as shown in FIGS. 5 and 6 by ion-implanting a p-type impurity at a second ion implantation concentration (ST104). The p-type impurity is, for example, boron (B) or aluminum (Al). According to the embodiment, the second concentration is, for example, 2×10¹⁷/cm³. That is, the second concentration is greater than the first concentration, and is 2 times the first concentration according to the embodiment. For example, when the n-type impurity concentration of the epitaxial layer is 1×10¹⁶/cm³ as described above, and when the first concentration (the n-type) is 1.0×10¹⁷/cm³, the second ion implantation concentration is set to 2.0×10¹⁷/cm³; and the second concentration (the p-type) becomes 2.×10¹⁷/cm³. A second carrier concentration (the holes) of the second semiconductor pillar region 4 becomes 1.0×10¹⁷/cm³.

The p-type impurity is ion-implanted into multiple locations of the active region 101 of a semiconductor layer 100B. According to the embodiment, the multiple locations are positioned on straight lines in the Y-direction at a spacing W2 in the X-direction. Thereby, the stripe-shaped second semiconductor pillar portion 41 is formed in the active region 101. Accordingly, stripe-shaped first semiconductor pillar portions 31 are formed in the regions of the active region 101 at which the second semiconductor pillar portions 41 are not formed. According to the embodiment, the width of the stripe-shaped regions of a mask M (see FIG. 6) through which the ions are implanted is a width W1 that is slightly less than the width W (<W) of the first and second semiconductor pillar regions 3 and 4 in FIG. 1; and the spacing of the mask M is a width W2 that is slightly greater than the width W (>W). Therefore, in the active region 101 of the semiconductor layer 100B, the first semiconductor pillar portion 31 of the width W2 and the second semiconductor pillar portion 41 of the width W1 are formed in stripe shapes having a periodic structure. For example, by performing activation processing described below for the width W1 of the second semiconductor pillar portion 41, the second semiconductor pillar region 4 changes from the width W1 to the width W due to diffusion of the p-type impurity; and the first semiconductor pillar region 3 accordingly becomes the width W.

Although the widths of the first and second semiconductor pillar regions 3 and 4 of the silicon carbide semiconductor device 200 shown in FIG. 1 according to the embodiment are described as being the same width W, for example, the widths of the regions 3 and 4 may have a 2-fold difference. In such a case, it is necessary for the carrier concentrations of the regions 3 and 4 after the carrier compensation effect to be equal. Here, carrier compensation effect refers to ion-implanting an impurity into a semiconductor to change the electron or hole concentration in the semiconductor by causing the coexistence of donors and acceptors. Thus, the concentration after carrier compensation is called the carrier concentration.

For example, the carrier concentration of the second semiconductor pillar region 4 that is fully depleted (in other words, has a maintained charge balance) is half of the carrier concentration of the first semiconductor pillar region 3 (the second carrier concentration), i.e., 5×10¹⁶/cm³, when the width of the first semiconductor pillar region 3 is set to 1 μm, the carrier concentration (the first carrier concentration) is set to 1×10¹⁷/cm³, and the width of the second semiconductor pillar region 4 is set to 2 μM.

Accordingly, the second semiconductor pillar region 4 is formed by ion-implanting a p-type impurity having the second concentration, i.e., 1.5×10¹⁷/cm³, into an n-type epitaxial layer having the first concentration, i.e., 1×10¹⁷/cm³. Due to the carrier compensation described above, the second semiconductor pillar region 4 has a carrier concentration of 5×10¹⁷/cm³.

Thus, when the widths of the first and second semiconductor pillar regions 3 and 4 are different, it is sufficient to ion-implant a p-type impurity into the second semiconductor pillar region 4 to cause full depletion, that is, to cause the sheet carrier concentrations of the first semiconductor pillar region 3 and the second semiconductor pillar region 4 to be equal. Here, the sheet carrier concentration refers to the concentration of the carrier concentration multiplied by the width of each pillar region. That is, sheet carrier concentration=(width of 1 μm of first semiconductor pillar region 3)×(first carrier concentration of 1×10¹⁷/cm³)=(width of 2 μm of second semiconductor pillar region 4×second carrier concentration of 5×10¹⁶/cm³).

As shown in FIGS. 5 and 6, the second semiconductor pillar portions 41 are formed in stripe shapes of the width W1 from the regions of the active region 101 of a semiconductor layer 100C into which the p-type impurity is ion-implanted via the mask M. Also, the first semiconductor pillar portions 31 are formed in stripe shapes of the width W2 from the regions of the active region 101 into which the p-type impurity is not ion-implanted. Thus, the first semiconductor pillar portion 31 and the second semiconductor pillar portion 41 are simultaneously formed.

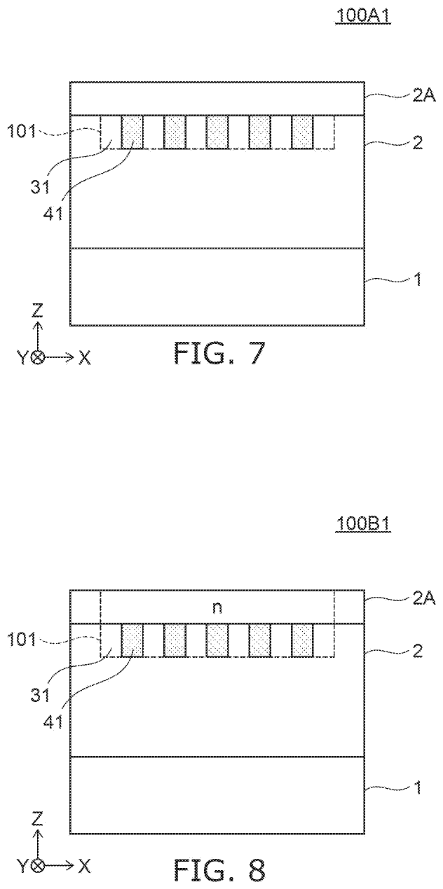

Then, as shown in FIG. 7, a semiconductor layer 2A that is an epitaxial layer having silicon carbide as a material is stacked on a semiconductor layer 2 (ST102).

Continuing as shown by a semiconductor layer 100B1 of FIG. 8, an n-type impurity is ion-implanted at the first ion implantation concentration into the entire region of the active region 101 of the semiconductor layer 2A (ST103).

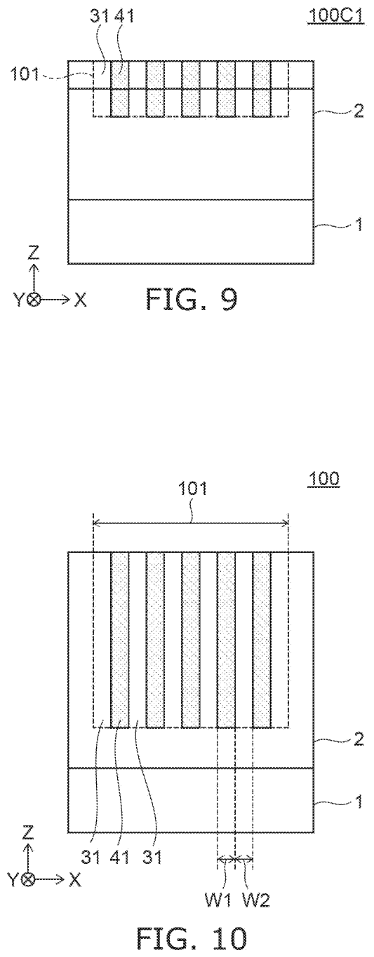

Then, a p-type impurity is ion-implanted at the second ion implantation concentration (ST104). As shown by a semiconductor layer 100C1 of FIG. 9, the stripe-shaped first semiconductor pillar portion 31 and the stripe-shaped second semiconductor pillar portion 41 are simultaneously formed to have a periodic structure. When stacking the semiconductor layer and performing ion implantation, the first semiconductor pillar portion 31 and the second semiconductor pillar portion 41 are formed in the same regions in the stacking direction by using the same mask M. The first semiconductor pillar portion 31 and the second semiconductor pillar portion 41 are stacked each time such processing is repeated. Thus, in the first ion implantation and in the second ion implantation when stacking the first semiconductor pillar portion 31 and the second semiconductor pillar portion 41, the ion implantations are performed so that at least the n-type impurity and the p-type impurity reach the first semiconductor pillar portion 31 and the second semiconductor pillar portion 41 formed once previously.

By performing the stacking and the ion implantation a specified number of times (ST105: YES), a semiconductor element 100 is formed as shown in FIG. 10; and the silicon carbide semiconductor device 200 is completed (ST106). This process includes, for example, the processes of forming the drain electrode 11, the base region 5, the source region 6, the insulating film 7, the control electrode 8, the source electrode 9, and the insulating film 10 in the semiconductor element 100. Furthermore, activation processing is performed in this process. The diffusion and annealing of the n-type impurity and the p-type impurity are performed in the activation processing. The drain electrode 1, the first semiconductor pillar region 3, the second semiconductor pillar region 4, the base region 5, the source region 6, the source electrode 9, and the control electrode 8 are electrically activated thereby. The multiple first semiconductor pillar portions 31 and the multiple second semiconductor pillar portions 41 that are stacked in the Z-direction are electrically activated to become the first semiconductor pillar region 3 and the second semiconductor pillar region 4. In the case of silicon carbide, for example, the annealing is performed at a high temperature of 1600° C. to 1900° C. Even when annealing the silicon carbide is performed, a change of the pillar shape due to the diffusion substantially does not occur; for example, the width of the second semiconductor pillar portion 41 slightly changes from the width W1 to the width W.

By performing such processes, the silicon carbide semiconductor device 200 shown in FIG. 1 is manufactured.

Concentration measurement results of the impurities of the active region 101 of the silicon carbide semiconductor device 200 shown in FIG. 1 will now be described with reference to FIGS. 11 and 12.

FIG. 11 shows an example of the measurement result of the n-type impurity.

In FIG. 11, the vertical axis is the measured concentration of the n-type impurity; and the horizontal axis is the distance in the active region 101. For example, the pillar depths shown by A-A of FIG. 1 and the region of the active region 101 in a cross section in a direction (the X-direction) perpendicular to the first and second semiconductor pillar regions 3 and 4 formed in the stripe shapes corresponding to the C-C cross section of FIG. 5 are shown. In the illustration, n shows the region of the first semiconductor pillar region 3; and p shows the region of the second semiconductor pillar region 4.

As shown in FIG. 11, the detected concentration of the n-type impurity is constant regardless of the region of the active region 101. According to the embodiment as described in reference to FIGS. 5 and 6 above, the n-type impurity is ion-implanted at the first ion implantation concentration into the entire region of the active region 101. Therefore, in the completed silicon carbide semiconductor device 200 after the activation processing as well, the n-type impurity is measured to be substantially the same concentration in both the first and second semiconductor pillar regions 3 and 4.

FIG. 12 shows an example of a measurement result of the p-type impurity.

In FIG. 12, the vertical axis is the measured concentration of the p-type impurity; and the horizontal axis is the distance in the active region 101 similar to FIG. 11. In the illustration, n shows the region of the first semiconductor pillar region 3; and p shows the region of the second semiconductor pillar region 4 similar to FIG. 11.

As shown in FIG. 12, the measured second concentration of the p-type impurity is different between the first semiconductor pillar region 3 and the second semiconductor pillar region 4. That is, the p-type impurities in the second semiconductor pillar regions 4 are measured to be substantially the same concentration, but the p-type impurity is not measured in the first semiconductor pillar regions 3.

Thus, in the silicon carbide semiconductor device 200 of the embodiment, the n-type impurity is measured in the entire region of the active region 101, but the p-type impurity is measured only in the second semiconductor pillar region 4 of the active region 101.

Thus, according to the method for manufacturing the silicon carbide semiconductor device 200, the silicon carbide semiconductor device 200 is manufactured by the process of ion-implanting the p-type impurity in stripe shapes at the second ion implantation concentration after ion-implanting the n-type impurity at the first ion implantation concentration into the entire region of the active region 101. Therefore, compared to the case where the p-type regions are formed by ion-implanting stripe shapes after forming the n-type regions by ion-implanting stripe shapes, it is unnecessary to align the masks of each stripe. Therefore, the manufacturing of the silicon carbide semiconductor device 200 can be easy.

According to the method for manufacturing the silicon carbide semiconductor device 200, in the first semiconductor pillar region 3, the n-type impurity is ion-implanted to have the first concentration; and in the second semiconductor pillar region 4, the p-type impurity is ion-implanted to have the second concentration that is 2 times the first concentration of the n-type impurity. Accordingly, the charge balance can be maintained between the first semiconductor pillar region 3 and the second semiconductor pillar region 4.

Because the charge balance can be maintained in the silicon carbide semiconductor device 200, a reduction of the breakdown voltage due to nonuniformity of the spreading of the depletion layer due to an imbalance of the charge balance when forming the depletion layer can be prevented.

In the silicon carbide semiconductor device 200, the overlap amount of the first and second semiconductor pillar regions 3 and 4 in a direction (the X-direction) perpendicular to the direction (the Y-direction) of the stripe shapes can be minimized in principle. Thereby, higher resistance, i.e., a rise of the element resistance due to confinement of the current path due to the carrier compensation of the overlapping portion, can be prevented.

Because silicon carbide is used as a material of the silicon carbide semiconductor device 200, the pillar shapes of the first and second semiconductor pillar regions 3 and 4 substantially do not change in the activation processing. Accordingly, in the silicon carbide semiconductor device 200, the reduction of the breakdown voltage due to the change of the charge balance occurring due to the change of the shapes of the first and second semiconductor pillar regions 3 and 4 in the activation processing can be prevented.

### Second Embodiment

A second embodiment differs from the first embodiment in that the depths of the first and second semiconductor pillar regions are configured to decrease in steps at the end portion of the silicon carbide semiconductor device. Accordingly, the configuration differences will now be described in detail. The same configurations as the first embodiment described above are marked with the same reference numerals.

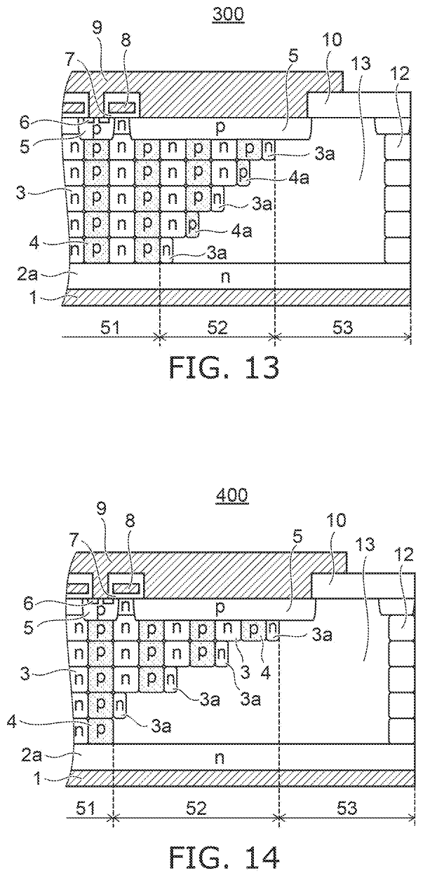

FIG. 13 is a schematic cross-sectional view showing an example of the structure of the end portion of a silicon carbide semiconductor device 300 of the embodiment.

As shown in FIG. 13, the end portion of the silicon carbide semiconductor device 300 includes a central region 51, a boundary region 52, and a termination region 53. The first semiconductor pillar region 3 and the second semiconductor pillar region 4 are formed to have the same depth in the central region 51. The boundary region 52 is between the central region 51 and the termination region 53. In the boundary region 52, the depths of the first and second semiconductor pillar regions 3 and 4 are configured to decrease in steps from the central region 51 toward the termination region 53. Also, in the termination region 53, a high resistance layer 13 is provided; and the insulating film 10 is located on the surface of the high resistance layer 13. A field stop layer 12 is provided at the outermost side of the termination region 53.

In the boundary region 52, the regions of a first semiconductor pillar region 3a and a second semiconductor pillar region 4a formed furthest on the termination region 53 side are respectively half of the regions of the other first semiconductor pillar regions 3 and second semiconductor pillar regions 4. That is, in each layer, the impurity amount of the pillar furthest on the termination region 53 side is one-half. The configuration that decreases in steps is possible by replacing the mask at each layer when performing the stacking.

Thus, in a structure of the boundary region 52 in which the depth of pillar decreases in steps, by setting the impurity amount of only the pillar furthest on the termination region 53 side in each layer to be one-half, the charge balance is improved, and a high breakdown voltage of the silicon carbide semiconductor device 300 is easily obtained.

FIG. 14 is a schematic cross-sectional view showing an example of the structure of the end portion of a silicon carbide semiconductor device 400 of the embodiment.

As shown in FIG. 14, in the boundary region 52 of the silicon carbide semiconductor device 400, the n-type impurity amount of the first semiconductor pillar region 3a is formed to be half of the other first semiconductor pillar regions 3 in the layers in which the first semiconductor pillar region 3 is furthest on the termination region 53 side. On the other hand, the p-type impurity amount of the second semiconductor pillar region 4 is the same for all of the second semiconductor pillar regions 4. Thus, the boundary region 52 may have such a structure that becomes shallower in steps. Although a configuration is described in which the n-type impurity of the first semiconductor pillar region 3 is one-half, the p-type impurity amount of the second semiconductor pillar region 4 may be half of the other second semiconductor pillar regions 4 in each layer in which the second semiconductor pillar region 4 is furthest on the termination region 53 side; and the n-type impurity amount of the first semiconductor pillar region 3 may be the same for all of the first semiconductor pillar regions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A method for manufacturing a silicon carbide semiconductor device, the method comprising:
forming a semiconductor layer on a substrate, the substrate including silicon carbide;
forming a first semiconductor region by implanting an impurity of a first conductivity type into the semiconductor layer, the first semiconductor region having a first concentration of the first conductivity type;
forming a first semiconductor pillar portion and a second semiconductor pillar portion by implanting an impurity of a second conductivity type into a plurality of locations of the first semiconductor region, the first semiconductor pillar portion being of the first conductivity type, the second semiconductor pillar portion having a second concentration of the second conductivity type and being adjacent to the first semiconductor pillar portion; and
repeating the forming of the semiconductor layer, the forming of the first semiconductor region, and the forming of the first and second semiconductor pillar portions.

2. The method according to claim 1, wherein
the second concentration is greater than the first concentration.

3. The method according to claim 1, wherein
the second concentration is 2 times the first concentration.

4. The method according to claim 1, further comprising:
forming a first major electrode connected to the semiconductor layer;
forming a second semiconductor region of the second conductivity type on the first and second semiconductor pillar portions;
forming a second major electrode in contact with the second semiconductor region; and
forming a control electrode on the first semiconductor region and the first semiconductor pillar portion with an insulating film interposed.

5. The method according to claim 1, wherein
a width of the first semiconductor pillar portion and a width of the second semiconductor pillar portion are a same width in a direction in which the first semiconductor pillar portion and the second semiconductor pillar portion are adjacent.

6. The method according to claim 1, wherein
a first sheet carrier concentration of the first semiconductor pillar portion and a second sheet carrier concentration of the second semiconductor pillar portion are equal.

7. The method according to claim 1, wherein
a first carrier concentration of the first semiconductor pillar portion and a second carrier concentration of the second semiconductor pillar portion are equal.

8. The method according to claim 1, wherein
when repeating the forming of the first and second semiconductor pillar portions, ion implantations are performed so that at least ions reach the first and second semiconductor pillar portions formed once previously.

9. A silicon carbide semiconductor device, comprising:
a semiconductor layer of a first conductivity type;
a first semiconductor pillar region formed on the semiconductor layer, the first semiconductor pillar region being of the first conductivity type and including an impurity having a first concentration;
a second semiconductor pillar region formed on the semiconductor layer, the second semiconductor pillar region being of a second conductivity type, being adjacent to the first semiconductor pillar region, and including the impurity of the first concentration and an impurity of a second concentration;
a first major electrode connected to the semiconductor layer;
a second semiconductor region formed on the first and second semiconductor pillar regions, the second semiconductor region being of the second conductivity type;
a second major electrode formed in contact with the second semiconductor region; and
a control electrode formed above the first semiconductor region and the first semiconductor pillar region with an insulating film interposed.

10. The device according to claim 9, wherein
the first semiconductor pillar region and the second semiconductor pillar region are adjacent to each other in a region between an element central region and a termination region, and
depths of the first and second semiconductor pillar regions decrease in steps toward the termination region.
